(19) United States
(12) Patent Application Publication
(10) Pub. No.: US 2004/0129954 A1
(43) Pub. Date: Jul. 8, 2004

(54) Embedded nonvolatile memory having metal contact pads

(76) Inventors: Yu-Ming Hsu, Hsinchu City (TW); Yen-Tai Lin, Hsinchu City (TW); Chien-Hung Ho, Hsinchu City (TW); Ching-Yuan Lin, Hsinchu Hsien (TW)

Correspondence Address: LAW OFFICES OF CLEMENT CHENG, 17220 NEWHOPE STREET #127, FOUNTAIN VALLEY, CA, 92708, US

(21) Appl. No.: 10/338,544

(22) Filed: Jan. 8, 2003

(51) Int. Cl. G11C 7/00; H01L 27/10

(52) U.S. Cl. 257/203; 257/209; 365/189.11; 365/189.12

(57) ABSTRACT

The present invention includes a nonvolatile memory structure comprising: nonvolatile memory cell area including write/erase pins, address pins and data input/output pins; conductive contact pads arranged at the periphery area of the nonvolatile memory cell area for power input to operate the nonvolatile memory cell, wherein the conductive contact pads are connected to a power selecting from a positive power, a negative power or the combination thereof. The conductive contact pads include a positive power pin or a negative power pin for providing the operating power.

### FIELD OF THE INVENTION

The present invention relates to a semiconductor device, and more specifically, to an embedded flash memory having additional powers pad and a level shifter for separating the logical device and saving the space used to implant the pumping circuits.

### BACKGROUND OF THE INVENTION

The semiconductor industry has been advanced to the field of Ultra Large Scale Integrated (ULSI) technologies. As the evolution of the IC industry, multi-level interconnection is also one of the trends for making the integrated circuits. The fabrication of the nonvolatile memories also follows the trend of the reduction of the size of a device. The nonvolatile memories include various types of devices, such as EAROM (electrically alterable read only memory), EEPROM (electrically erasable programmable read only memory). Different types of devices have been developed for specific applications requirements in each of these segments. These parts have been developed with a focus on the high endurance and high-speed requirements.

Flash memory is one of the segments of nonvolatile memory devices, which includes a floating gate to storage charges and an element for electrically placing charge on and removing the charges from the floating gate. From the view of structure, the devices are divided into stack-gate type and split-gate type. The portable telecommunications and computing have become a major driving force in the field of integrated circuits. One of the applications of flash memory is BIOS for computer. Typically, the high-density nonvolatile memories can be applied as the mass storage of portable handy terminals, solid-state camera and PC cards. That is because that the nonvolatile memories exhibit many advantages, such as a fast access time, low power dissipation, and robustness. The flash needs very few power to erase the data section block by block, this is faster than traditional type memory.

The formation of nonvolatile memories towards the trends of low supply power and fast access, because these requirements are necessary for the application of the mobile computing system. Flash memory needs the charges to be hold in the floating gate for a long periods of time. Therefore, the dielectric that is used for insulating the floating gate needs to be high performance. At present, the low voltage flash memory is applied with a voltage of about 3V or 5V during charging or discharging the floating gate. As known in the art, tunneling is a basic technology in charging or discharging. In order to attain high tunneling efficiency, the thickness of the dielectric between the floating gate and substrate have to be scaled down due to the supply voltage is reduced. In such device, electrical alterability is achieved by Fowler-Nordheim tunneling which is cold electron tunneling through the energy barrier at a silicon-thin dielectric interface and into the oxide conduction band. Typically, the thin dielectric layer is composed of silicon dioxide and the thin silicon dioxide layer allows charges to tunnel through when a voltage is applied to the gate. These charges are trapped in the silicon dioxide and remain trapped there since the materials are high quality insulators. U.S. Pat. No. 6,174,759 to Verhaar disclosed a method for making embedded flash memory and issued on Jul. 16, 1999, entitled “Method of manufacturing a semiconductor device” and assigned to U.S. Pillips Coporation. The prior art disclosed a method which is intergratable with the standard CMOS process.

Typically, the flash device needs a circuit for pumping the voltage level for the memory cell and the circuit is called pumping circuits. The function of the pumping circuits is to transform the input voltage to a predetermined level. The memory of IC generally includes internal operating voltage and that is different form the voltage level for the periphery circuits and operating system. The pumping circuits is used to change the voltage between the input and output terminals. The pumping circuits belong to logic device and they occupied a large space in the memory cell. Therefore, what is needed is to simplify the structure of the memory cell.

### SUMMARY OF THE INVENTION

The object of the present invention is to provide an embedded flash memory with contact pad.

The further object of the present invention is to provide a simplified structure for the flash memory cell.

The present invention includes a nonvolatile memory structure comprising: nonvolatile memory cell area including write/erase pins, address pins and data input/output pins; conductive contact pads arranged at the periphery area of the nonvolatile memory cell area for power input to operate the nonvolatile memory cell, wherein the conductive contact pads are connected to a power selecting from a positive power, a negative power or the combination thereof. The conductive contact pads includes a positive power pin or a negative power pin for providing the operating power.

The nonvolatile memory cell area includes: pluralities of nonvolatile memory cells; a first level shifter connected to a common word line (WL) of the pluralities of nonvolatile memory cells, terminals of the first level shifter being respectively connected to the positive power contact pad and the address pins and a negative power pad through a power switch macro; a second level shifter connected a common bit line (BL) of the pluralities of nonvolatile memory cells, wherein the second level shifter is respectively connected to the positive power contact pad and ground; and wherein the first level shifter and the second level shifter are implanted into the nonvolatile memory structure for separating a logical device from the nonvolatile memory structure.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows the structure according to the present invention.

FIG. 2 is the circuit of the embedded flash memory according to the present invention.

### DETAILED DESCRIPTION OF THE PREFERRED EMBODIMENT

The present invention proposes a novel structure for an embedded flash nonvolatile memory. In the present invention, an additional power pad and level shifter are implanted in the memory cell for operating under different power. The structure may save the space used to implant the pumping circuits. Further, the logical device can be separated from the nonvolatile memory.

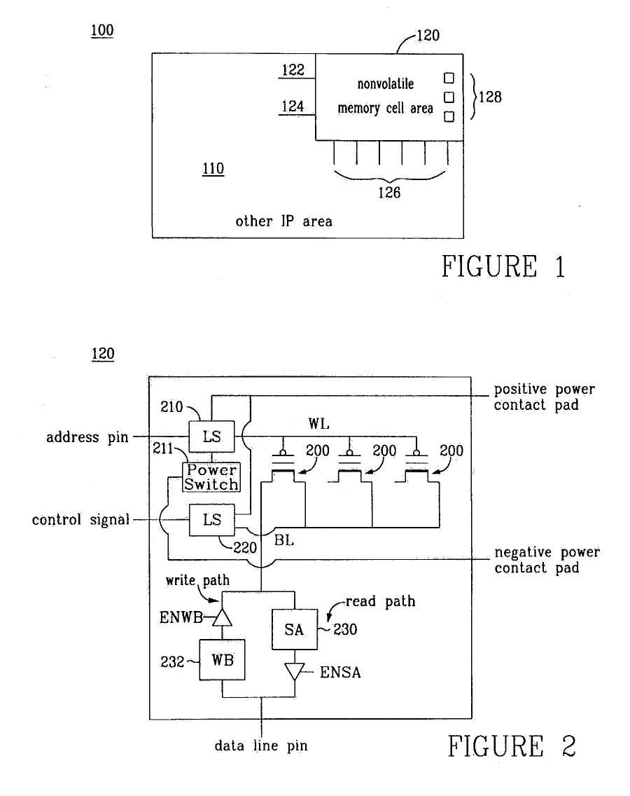

The detail description will be seen as follows, as shown in the FIG. 1, the indication 100 represents the circuit structure according to the present invention. The structure 100 includes other IP area 110 and the flash or nonvolatile memory cell area 120. The nonvolatile memory cell area 120 includes write/erase pins 122, address pins 124 and data input/output pins 126. Pluralities of conductive contact pad 128 are arranged at the periphery area of the nonvolatile memory cell area 120 for power input to operate the device. For example, the conductive contact pad 128 includes positive power pin coupled to the positive bias, such as 7 volts, to provide the positive power for operating the memory cell. Negative power pin is coupled to the negative bias, such as ground, 7 volts, to provide the negative power for operating the memory cell. A reference voltage contact pin is connected to the voltage level Vcc. The above mentioned voltage scale is used for reference not used for limiting the scope of the present invention. The addition power supply according to the present invention could be a monopole power or bipolar power.

FIG. 2 shows the embodiment of the nonvolatile memory cell area 120 in FIG. 1. The nonvolatile memory cell area 120 includes pluralities of nonvolatile memory cells 200, the common word line (WL) of the devices 200 is coupled to the first level shifter (LS) 210. The terminals of the first level shifter (LS) 210 are respectively connected to a first positive power contact pad (7 volts or Vcc), a second negative power contact pad (−7 volts through a power switch 211 and the address pins. The common bit line (BL) of the devices 200 is coupled to the second level shifter (LS) 220. The terminals of the second level shifter (LS) 220 are respectively connected to the second positive power contact pad (+7 volts) and control signal.

A common node of the bit line (BL) and the second level shifter (LS) 220 is coupled to a pair of devices consisting of a sensor amplifier (SA) 230 controlled by ENSA via a first diode and a write buffer (WB) 232 controlled by ENWB via a second diode. The common node of the write buffer (WB) 232 and the first diode are connected to the data line pin. If the operating voltage level is not so high, then the sensor amplifier 230 can be omitted. For example, the operating current of PMOS is small the sensor amplifier 230 can be removed according to the present invention, thereby further simplifying the structure.

The level shifter transforms the input level to a predetermined voltage level and typically used as a buffer. The memory device of IC generally includes internal operating voltages that are different from the power for periphery circuit or the system. The so-called scalable level buffer may receive an input power in a certain range and shifts the input voltage level to a predetermined voltage level range.

The present invention uses the level shift to separate the logical device from the memory device in order to achieve the goal of simplifying the structure of memory cell. Under the operating of some memory cell, the voltage is lower than the write/erase breakdown voltage of device, hence, the structure may couples to Vcc via the positive power pin and couples to the Vss via the negative power pin. In the embodiment, the structure may force some PMOS flash cell is operated by using Vcc to 5V/6V (in pre-burning area) to obtain the write and erase mode. The data stored by the memory cell is read using normal voltage level. Apparently, the structure separates the pumping circuits from the memory cell to the periphery circuits area. During the write/erase mode, the present invention uses two additional pins for writing data into or erasing the data from the memory cell. During the read mode, the present invention forces the normal voltage level to Vcc/GND to read the data stored in the memory cell. In one time programming (OTP) product, if the above operating conditions are used, there is security issue has to be concerned and the flash is desired to be used for storing the data to avoid from being decoded.

In the application of multiple time programming, the high-level power generator in the system board will force the embedded flash memory to perform the write/erase function. Some memory cell needs only 5/6 V for writing or erasing, in the case, the additional contact pad is not necessary and the cell is bias to Vcc (3V) contact pad to obtain the purpose of writing or erasing.

The voltage levels for the operation modes are list as follows. It is used for an example rather than limiting the invention.

Programming mode:

Word line: bias to 0 volts;

Bit line: bias to 0 volts;

Source line: 7 volts.

Erase mode:

Word line: bias to −7 volts;

Bit line: floating;

Source line: bias to −+7 volts.

Read mode:

Word line: bias to 0 volts;

Bit line: 1 volts;

Source line: bias to 3.3 volts.

The benefits of the present invention include: saving the area used to form the pumping circuits, especially to the PMOS flash. For the cell only needs 5V/6V to perform write/erase mode, the high-level voltage circuits is omitted. The structure forces the level of Vcc rising to 5V/6V for writing/erasing during the write/erase mode, and backs to Vcc for reading the data in the cell. In the OTP product, we do not need the higher level power in the memory board.

As will be understood by persons skilled in the art, the foregoing preferred embodiment of the present invention is illustrative of the present invention rather than limiting the present invention. Having described the invention in connection with a preferred embodiment, modification will now suggest itself to those skilled in the art. Thus, the invention is not to be limited to this embodiment, but rather the invention is intended to cover various modifications and similar arrangements included within the spirit and scope of the appended claims, the scope of which should be accorded the broadest interpretation so as to encompass all such modifications and similar structures.

While the preferred embodiment of the invention has been illustrated and described, it will be appreciated that various changes can be made therein without departing from the spirit and scope of the invention.

What is claimed is:

1. A nonvolatile memory structure comprising:
nonvolatile memory cell area including write/erase pins, address pins and data input/output pins;
conductive contact pads arranged at the periphery area of said nonvolatile memory cell area for power input to operate said nonvolatile memory cell, wherein said conductive contact pads are connected to a power selecting from a positive power, a negative power or the combination thereof.

2. The structure of claim 1, wherein said conductive contact pads includes a first positive power pin or a second position power pin for providing the operating power.

3. The structure of claim 1, wherein said nonvolatile memory cell area includes:
pluralities of nonvolatile memory cells;
a first level shifter connected to a common word line (WL) of said pluralities of nonvolatile memory cells, terminals of said first level shifter being respectively connected to said positive power contact pad, said negative power pad through a power switch and said address pins;
a second level shifter connected a common bit line (BL) of said pluralities of nonvolatile memory cells, wherein said second level shifter is respectively connected to said positive power contact pad and control signal; and
wherein said first level shifter and said second level shifter are implanted into said nonvolatile memory structure for separating a logical device from said nonvolatile memory structure.

4. The structure of claim 3, wherein said nonvolatile memory cell area further includes:
a sensor amplifier connected to a common bit line via a first node and connected to a data line pin via a second node.

5. The structure of claim 2, wherein during the operation, a write/erase voltage is relatively low to the one of the breakdown voltage of said nonvolatile memory cell, thus coupling said positive power pin to Vcc and coupling said negative power pin to Vss.

6. The structure of claim 5, wherein said nonvolatile memory structure forces said Vcc raising to a voltage higher than Vcc for writing/erasing during said write/erase mode, and backs to said Vcc for reading the data in said nonvolatile memory cell.

7. A nonvolatile memory cell area includes:
pluralities of nonvolatile memory cells;
a first level shifter connected to a common word line (WL) of pluralities of nonvolatile memory cells, terminals of said first level shifter being respectively connected to a first positive power contact pad, a negative power pad through a power switch and an address pins;
a second level shifter connected a common bit line (BL) of said pluralities of nonvolatile memory cells, wherein said second level shifter is respectively connected to said positive power contact pad and ground; and
wherein said first level shifter and said second level shifter are implanted into said nonvolatile memory structure for separating a logical device from said nonvolatile memory structure.

8. The structure of claim 7, wherein said nonvolatile memory cell area further includes:
a sensor amplifier connected to a common bit line via a first node and connected to a data line pin via a second node.
